(19) United States
(12) Patent Application Publication
(10) Pub. No.: US 2003/0045128 A1
(43) Pub. Date: Mar. 6, 2003

(54) Wafer transfer method performed with vapor thin film growth system and wafer support member used for this method

(75) Inventors: Shyuji Tobashi, Shibata-city (JP); Tadashi Ohashi, Kudamatu-city (JP); Katsuyuki Iwata, Kudamatu-city (JP); Shinichi Mitani, Numazu-city (JP); Hideki Arai, Numazu-city (JP); Hideki Ito, Numazu-city (JP)

Correspondence Address: FOLEY AND LARDNER, SUITE 500, 3000 K STREET NW, WASHINGTON, DC, 20007, US

(73) Assignee: TOSHIBA KIKAI KABUSHIKI KAISHA

(21) Appl. No.: 10/125,588

(22) Filed: Apr. 19, 2002

Related U.S. Application Data
(63) Continuation-in-part of application No. 09/736,188, filed on Dec. 15, 2000.

(30) Foreign Application Priority Data
Dec. 21, 1999 (JP) 11-362178

(51) Int. Cl. H01L 21/31

(52) U.S. Cl. 438/784

(57) ABSTRACT

A wafer transfer method, by which, when a wafer is loaded into a system, heat shock applied to the wafer can be relieved, the frequency of occurrence of crystal dislocation such as slip can be decreased, and productivity can be improved due to saving of energy and time required for heating and cooling of the system, and there is also provided a wafer support member used for this method. In this method, a step for transferring wafers so as to replace a wafer, which finishes its thin film growth process, with a following wafer, which is to be subjected to its thin film growth process, is carried out under the temperature being higher than the room temperature, while the wafer 1 is transferred integrally with a wafer support member 2 used for the thin film growth process.

### CROSS REFERENCE TO RELATED APPLICATIONS

This application is a continuation-in-part of U.S. application Ser. No. 09/736,188 filed on Dec. 15, 2000, which is expressly incorporated by reference in its entirety.

### FIELD OF THE INVENTION

This invention relates to a wafer transfer method performed with a vapor thin film growth system and also to a wafer support member used for this method. More particularly, this invention relates to a wafer transfer method performed in a step for transferring wafers so as to replace a treated wafer with a following wafer to be treated in a thin film growth process with a continuous single wafer processing vapor thin film growth system, in which each wafer of a semi-conductor such as a silicon substrate is continuously treated sheet by sheet, and this invention relates also to a wafer support member used for this method.

### BACKGROUND OF THE INVENTION

Lately, in the field of semi-conductor industry, a single wafer processing system is applied widely, due to its many characteristics, comparing with batch processing system.

For example, a single wafer processing epitaxial film growth system is necessary for the deposition process of a thin film such as an epitaxial film and a CVD film for each wafer having an increased diameter, because in the resultant film, in-plane characteristics are stable.

Particularly, in these days, automation technology for replacing a treated wafer with a following wafer to be treated has been improved so that throughput has been further advanced. Therefore, the single wafer processing vapor thin film growth system, where each wafer can be continuously treated sheet by sheet, has been applied generally.

Will be explained this conventional single wafer processing vapor thin film growth system. For example, as shown in FIG. 4, the conventional system includes, at the upper portion of its reactor 40, usually plurality of gas inlets 47, through which feed gas and carrier gas are introduced into the reactor 40; and a flow adjusting plate 48 provided with plurality of apertures 48a, through which the gas flow is adjusted. The conventional system also includes, below this flow adjusting plate 48, a wafer holder section B, into which a wafer 41 is loaded; a rotation axis 49, around which the wafer holder section B is rotated; and a heater 43. Additionally, a motor (not shown), by which the above rotation axis 49 is driven to rotate; usually plurality of gas outlets 50, through which exhaust gas containing unreacted gas from the reactor 40 is discharged; and a controller (not shown) for these gas outlets are connected to the lower section of the reactor, usually in the vicinity of the reactor's bottom.

Further, as shown in an enlarged sectional view of FIG. 5, the wafer holder section B, into which the wafer 41 is loaded, includes, for example, a wafer support member 42, which has a recess 42a formed on its upper surface for placing the wafer; and a lifting pin 44, which is used when the wafer 41 is placed on and removed from the above recess 42a.

In the single wafer processing vapor thin film growth system, which continuously treats each wafer sheet by sheet, a wafer, which finishes its thin film growth process, is replaced with a following wafer, which is to be subjected to its thin film growth process, under the temperature being generally higher than the room temperature. That is to say, this wafer replacing operation is carried out under the temperature being more closer to the temperature for the growth of the thin film, which allows the wafer to be cooled and heated in short time, resulting in quick growth of the thin film.

However, in this case, large temperature gap is generated between the wafer, which is introduced into the reactor under the room temperature, and the wafer support member, which is already heated in the reactor. Then, when the wafer is brought into contact with the wafer support member, temperature gap is generated in the wafer. Accordingly, if the wafer is directly supported on the wafer support member, heat shock will be produced in the wafer due to the wafer's temperature gap. As a result, since this heat shock may cause crystal defect such as strain and slip dislocation, damage may be caused in the wafer.

In order to solve such problem, for example, in the conventional vapor thin film growth process, after the wafer is introduced into the reactor, an operation is carried out, where the wafer is pre-heated on the lifting pin so that the temperature gap between the wafer and the wafer support member is decreased.

This pre-heating operation will be explained closely, referring to FIG. 5. The wafer 41 is loaded into the reactor 40 by a loading and unloading robot 45. The loaded wafer 41 is lifted so as to be located above the heater 43 by the lifting pin 44. Then, the wafer 41 is pre- heated for the predetermined time until the temperature gap between the wafer and the wafer support member becomes to fall within the predetermined temperature range, and the wafer is placed on the recess 42a.

In the above conventional vapor thin film growth process, during the growth of the thin film, impurities are attached to not only the wafer but also to the wafer support member 42 having an exposed surface to the reactive gas. Then, during the operation of the single wafer processing vapor thin film growth system, some of impurities attached to the wafer support member are released therefrom and contaminate the wafer. Therefore, in the conventional method, such impurities should be removed periodically.

As stated above, in the conventional vapor thin film growth process, after loading the wafer into the reactor, the wafer is pre-heated on the lifting pin in order to decrease the temperature gap between the wafer and the wafer support member. However, due to distance between the heater and the wafer held on the lifting pin, it takes long time to heat the wafer, which delays the growth of the thin film.

Further, the recess is usually formed on the surface of the wafer support member for placing the wafer, which means that the wafer support member has thickness difference between its central portion and its peripheral portion. This generates a heat capacity gap between the central portion and the peripheral portion in the wafer support member.

In this connection, at the moment when the wafer is supported on the wafer support member or during heating of the wafer, temperature gap tends to be generated also in the wafer between its outer peripheral area and its central area, because its outer peripheral area is brought into contact with the peripheral portion of the wafer support member, while its central area is not. This temperature gap generated in the wafer causes crystal dislocation such as slip.

Additionally, in order to remove the impurities attached to the wafer support member, the thin film growth process for each wafer should be shut down temporally for cleaning the wafer support member and after that, the process should be started again. As a result, the availability, i.e., productivity of the system is lowered, which results in high cost in performing the conventional thin film growth process.

### SUMMARY OF THE INVENTION

The present invention is attained in order to solve the above technical problems and has an object to provide a wafer transfer method which can relieve heat shock applied to each wafer loaded into a system so that crystal dislocation such as slip can be decreased and which can save energy and time required for heating and cooling the system so that the productivity is improved, and provide also a wafer support member used for this method.

Another object of the present invention is to provide a wafer transfer method, in which impurities can be removed from a wafer support member outside of the vapor thin film growth system without shutting down the thin film growth process so that the productivity of this system can be improved.

In accordance with one aspect of the present invention, there is provided a wafer transfer method performed with a continuous single wafer processing vapor thin film growth system, in which each wafer is continuously treated sheet by sheet and heated from its back side, the method comprising a step for transferring wafers so as to replace a wafer, which finishes its thin film growth process, with a following wafer, which is to be subjected to its thin film growth process, under the temperature being higher than the room temperature, while the wafer is transferred integrally with a wafer support member used for the thin film growth process.

In one preferred embodiment of the above wafer transfer method in accordance with the present invention, the step for transferring wafers so as to replace them is carried out under the temperature of 500° C. to 1000° C. in the system.

In another preferred embodiment of the above wafer transfer method in accordance with the present invention, the above wafer support member is fabricated from the same material of the wafer, and in still another preferred embodiment, a recess is formed on the above wafer support member for placing the wafer so that the depth of the recess has substantially the same dimension as the thickness of the wafer.

In another preferred embodiment of the present invention, each wafer subjected to the above thin film growth process is a silicon wafer.

Finally, in accordance with another aspect of the present invention, there is provided a wafer support member used for a thin film growth process, the member being fabricated from the same material of a wafer subjected to the thin film growth process and having a recess for placing the wafer so that the depth of the recess has substantially the same dimension as the thickness of the wafer.

The wafer transfer method in accordance with the present invention is characterized with that the wafer is transferred integrally with the wafer support member used for the thin film growth process performed with the single wafer processing vapor thin film growth system. If only the wafer is directly loaded into the heated reactor without the wafer support member, heat shock will be produced there due to the wafer's temperature gap. However, in the present invention, the wafer is supported in the wafer support member and loaded integrally into the reactor as they are. Therefore, damage, which might be caused by the above heat shock, can be decreased.

Additionally, the treated wafer can be replaced with the following wafer to be treated under higher temperature, resulting in that the thin film growth process can be carried out more quickly.

Further, the wafer support member can be fabricated from the same material of the wafer and the depth of the recess formed on the wafer support member can have substantially the same dimension as the thickness of the wafer. Accordingly, the total thickness, which is obtained by adding the thickness of the wafer to the thickness of the wafer support member while the wafer is supported on the wafer support member, becomes to be uniform throughout the global surface of the wafer. Therefore, when the wafer is supported on the wafer support member, the temperature gap in the wafer between its central area and its peripheral area, which might be caused by the wafer's partial heat capacity gap, can be decreased to the minimum value.

Finally, the impurities attached to the wafer support member can be removed outside of the vapor thin film growth system, hence, the thin film growth process for the wafer is not required to be shut down for every removing operation, which leads to improved productivity.

### BRIEF DESCRIPTION OF THE DRAWINGS

FIG. 1 is a schematic cross sectional view showing the construction of a wafer holder section in a single wafer processing vapor thin film growth system in accordance with the present invention;

FIG. 2 is a graph showing two curves, temperature vs. time at the central area and at the peripheral area in the wafer supported on the wafer support member during heating and cooling in a conventional vapor thin film growth process performed with a conventional single wafer processing vapor thin film growth system;

FIG. 3 is a graph showing two curves, temperature vs. time at the central area and at the peripheral area in the wafer supported on the wafer support member during heating and cooling in a vapor thin film growth process where a wafer transfer method in accordance with the present invention is performed with a single wafer processing vapor thin film growth system in accordance with the present invention;

FIG. 4 is a schematic cross sectional view showing the structure of a reactor of a conventional single wafer processing vapor thin film growth system; and

FIG. 5 is a schematic cross sectional view showing the structure of a wafer holder section of a conventional single wafer processing vapor thin film growth system.

FIG. 6 is a schematic cross sectional view showing the construction of a wafer holder section in a single wafer processing vapor thin film growth system in accordance with another embodiment of the present invention.

### DESCRIPTION OF THE PREFERRED EMBODIMENTS

Now, the present invention will be explained more concretely, referring to the accompanied drawings. In the following description, the present invention will be explained with an embodiment of silicon epitaxial film growth for each silicon wafer. However, the application field of the present invention is not limited to this example.

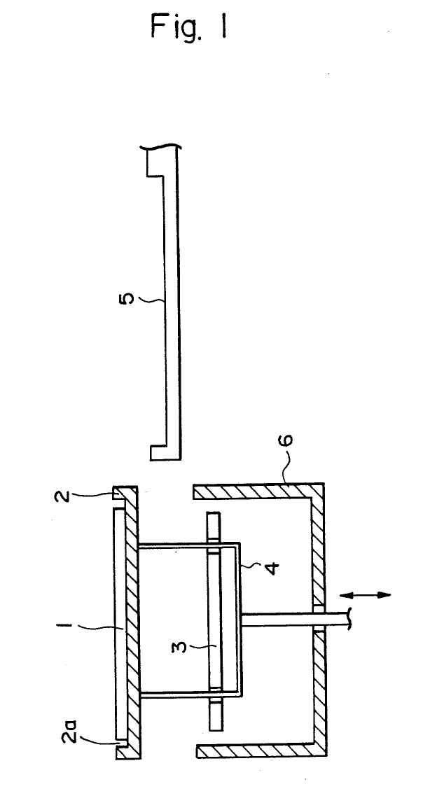

FIG. 1 shows an example of a wafer holder section (corresponding to B section in a single wafer processing vapor thin film growth system) in a single wafer processing vapor thin film growth system, where a wafer transfer method in accordance with the present invention is performed.

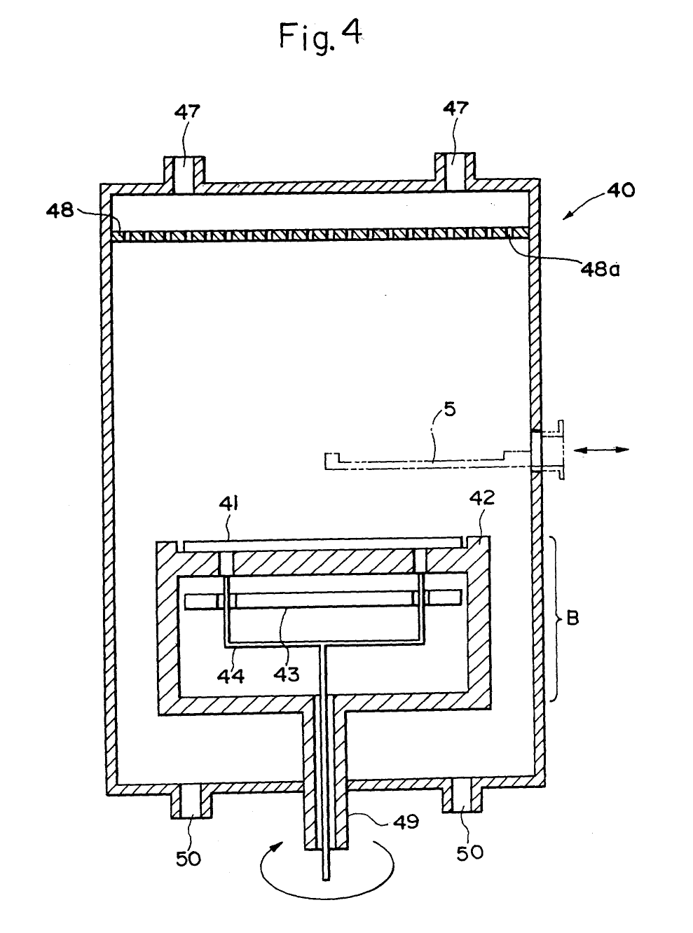

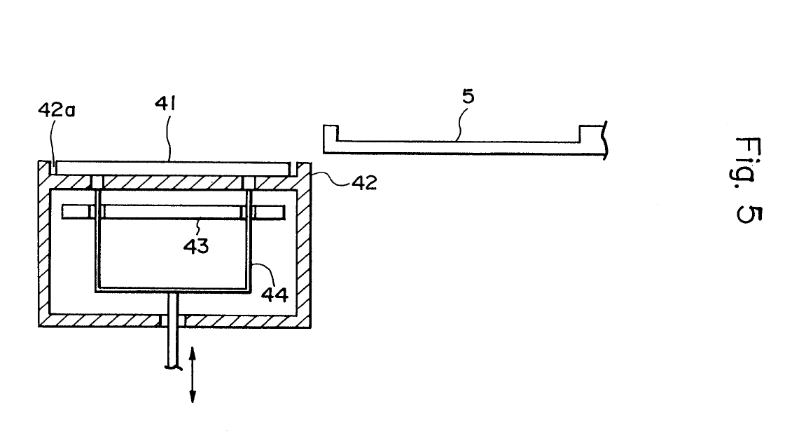

In the single wafer processing vapor thin film growth system in accordance with the present invention, at least one gas inlet and an adjusting plate are provided in the upper portion of a reactor, and below the adjusting plate, a wafer holder section, a holder rotation axis and a heater are provided. Then, a motor, at least one gas outlet and their controller are provided in the lower portion (usually in the vicinity of the bottom) of the reactor. The above wafer holder section includes a wafer support member 2 (42 in FIGS. 4 and 5), a lifting pin 4 (44 in FIGS. 4 and 5) and a bearing member 6. In this connection, the single wafer processing vapor thin film growth system in accordance with the present invention is configured in the same manner as the conventional system (See FIGS. 4 and 5).

However, the system of the present invention is different from the conventional system in that, first, the lifting pin 4 can lift the wafer 1 integrally with the wafer support member 2, while the wafer 1 is supported in the wafer support member 2, and next, a loading and unloading robot 5 can contain and hold the wafer support member 2 integrally with the wafer, while the wafer 1 is supported in the wafer support member 2.

Precisely, in the system in accordance with the present invention, the wafer 1 is loaded into the reactor through the means of the loading and unloading robot 5, while the wafer 1 is supported in the wafer support member 2. Then, the wafer 1 is lifted integrally with the wafer support member 2 by the lifting pin 4, and after the loading and unloading robot 5 is taken away from the reactor, the wafer is located at a predetermined position. During this operation, due to temperature gap between the wafer support member 2 and the bearing member 6 holding this member, heat shock is applied to the wafer support member 2, but the heat shock is not applied to the wafer 1 itself.

After that, the wafer 1 and the wafer support member 2 are heated for a predetermined time to the predetermined temperature.

In the present invention, the wafer support member 2 may be fabricated from a material, which is usually used for this type of wafer support member, such as graphite, quartz, and silicon. However, it is not limited to these materials. Particularly, the material, with which the wafer support member 2 is fabricated, is preferably same as the material (e.g., silicon) of the wafer substrate to be processed. Then, it is particularly prefer that the depth of a recess 2a, which is formed on the upper surface of the above wafer support member 2 for placing the wafer, has the substantially same dimension of the thickness of the wafer substrate 1.

Precisely, if the wafer 1 is fabricated from the same material of the wafer support member 2 and the total thickness obtained by adding the thickness of wafer 1 to that of the wafer support member 2 is almost uniform throughout the global surface of the wafer 1 during heating of the wafer and the wafer support member, the heat capacity is stable in the wafer support member 2 between its several portions, for example between its central portion and its peripheral portion, while the wafer 1 is supported on the wafer support member 2. Accordingly, in the wafer between its central area and its peripheral area, the temperature gap derived from heating and cooling can be decreased.

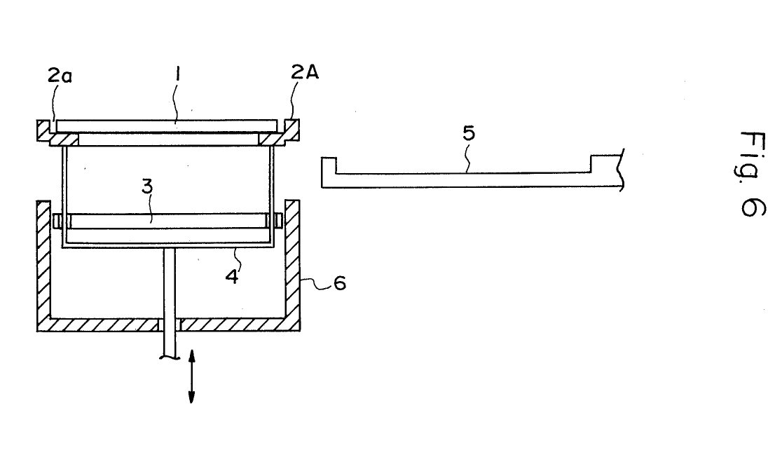

In the embodiment according to FIG. 1, the recess of the wafer support member supports entire back surface of the wafer. However, as shown in FIG. 6, the wafer support member 2A can be formed in ring-shaped to support only outer periphery section of the wafer. If only the wafer is directly loaded into the heated reactor without the wafer support member, heat shock will be produced there due to the wafer's temperature gap. However, in the present invention, the wafer is supported in the wafer support member and loaded integrally into the reactor as they are. Therefore, damage, which might be caused by the above heat shock, can be decreased.

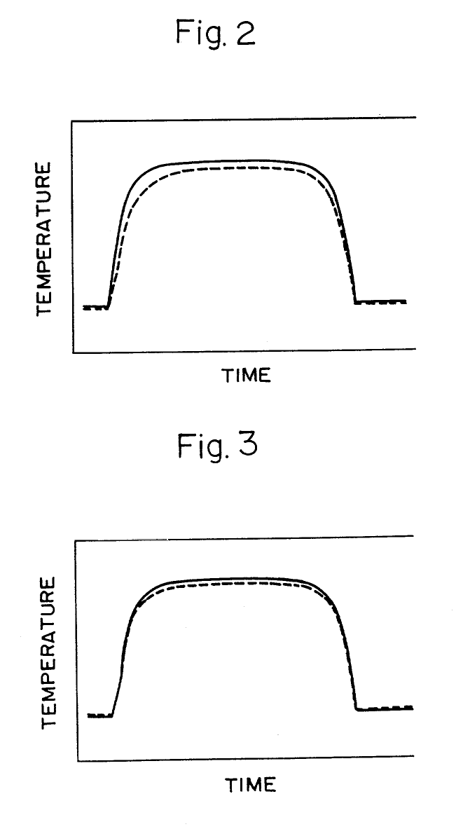

Referring to FIG. 2 (the conventional system) and FIG. 3 (the present system), each graph illustrating two curves, temperature vs. time at the central area and at the peripheral area, respectively, in the wafer supported on the wafer support member. In the case of the conventional system, the wafer support member is fabricated from the material (e.g., quartz glass), which is different from the material of the wafer to be treated (e.g., silicon). On the other hand, in the case of the present system, the wafer support material is fabricated from the same material of the wafer to be treated (e.g., silicon) and the depth of the recess has the same dimension of the thickness of the wafer. Then, the two systems are operated so that the heating and cooling conditions in the reactors are same (That is to say, near the wafer holder sections in reactors of these two systems, the almost same patterns are obtained related to the cooling and heating and to the time). In each Figure, the continuous line shows the temperature at the central area of the wafer, while the dotted line shows the temperature at the peripheral area of the wafer. By the consideration on the basis of comparison of two graphs FIGS. 2 and 3, it is found that in FIG. 2, there is temperature gap to some degree, but in FIG. 3, there is not significant temperature gap. Thus, the above mentioned effect can be confirmed clearly.

In the wafer transfer method in accordance with the present invention, it is prefer that the step for transferring the wafers so as to replace them is carried out under the temperature of 500° C. to 1000° C.

If the temperature is below 500° C., during heating and cooling, there will not be significant difference between the present method and the conventional method in the frequency of occurrence of crystal defect such as slip dislocation. Accordingly, one of effects of the present invention can not be sufficiently obtained, i.e., slip dislocation or the like can not be prevented reliably. Additionally, the large temperature gap leads the delay of heating and cooling operation (decreased productivity) and increased energy consumption.

On the other hand, if the operation temperature is above 1000° C., the frequency of occurrence of slip dislocation and the like is increased.

Conventionally, the thin film growth process on the wafer must be shut down for removing the impurities attached to the wafer support member. However, in the present invention, such removing operation can be carried out outside of the vapor thin film growth system without shutting down the thin film growth process. This is a further advantage of the present method.

For example, in order to remove the silicon film attached to the wafer support member, the wafer support member is dipped into the mixed acid of nitric acid and hydrofluoric acid outside of the vapor thin film growth system without shutting down the thin film growth process.

Therefore, the availability of the vapor thin film growth system is further improved comparing with the conventional system, which leads much higher productivity.

### EXAMPLE 1

For a single wafer processing vapor thin film growth system in accordance with the present invention, a system having the following structure was used. Precisely, at least one gas inlet and an adjusting plate are provided in the upper portion of a reactor, and below the adjusting plate, a wafer holder section, a rotation axis of the wafer holder section and a heater are provided. At the bottom of the reactor, a motor for driving the rotation axis and at least one gas outlet are provided. As shown in FIG. 1, the above wafer holder section is comprised of a wafer support member (fabricated from silicon), which has a recess formed on its upper surface for placing the wafer; a lifting pin, which is configured so as to load and unload the wafer integrally with the wafer support member, while the wafer is supported in the support member; and a bearing ring, which holds the wafer support member.

By means of the above system, each silicon wafer having the diameter of □□300 nm was continuously treated sheet by sheet so as to carry out a silicon epitaxial film growth process.

The epitaxial film growth process was carried out under the temperature of 1000° C., while a step for transferring wafers so as to replace a treated wafer with a following wafer to be treated was performed under the temperature of 700° C. in the reactor.

The frequency of occurrence of slip dislocation of the treated wafer was evaluated with a differential interference microscope. The result is shown in Table 1.

### COMPARATIVE EXAMPLE 1

By means of the conventional single wafer processing vapor thin film growth system shown in FIG. 4 (whole system) and FIG. 5 (wafer holder section), in the same manner as Example 1, each silicon wafer having the diameter of □□300 nm was continuously treated sheet by sheet so as to carry out a silicon epitaxial film growth process.

The epitaxial film growth process was carried out under the temperature of 1000° C., while in a step for transferring wafers so as to replace a treated wafer with a following wafer to be treated, after the wafer to be treated was loaded into the reactor, the wafer was pre-heated to the temperature of 700° C. on the lifting pin.

The frequency of occurrence of slip dislocation of the treated wafer was evaluated with a differential interference microscope. The result is shown in Table 1.

TABLE 1

| | Frequency |
|---|---|
| | of occurrence of slip dislocation of wafer |
| Example 1 | 0% |
| Comparative Example 1 | 15% |

As shown in Table 1, in the conventional method wherein the pre-heating is carried out, under the pre-heating temperature of 700° C., the slip dislocation was occurred on the wafer, on the other hand, in the wafer transfer method in accordance with the present invention, even under the wafer's loading and unloading temperature of 700° C., the slip dislocation was not occurred on the wafer.

### EXAMPLE 2

The processes and evaluations related to the frequency of occurrence of slip dislocation were carried out in the same way as in Example 1. However, in each process, a step for transferring wafers so as to replace a treated wafer with a following wafer to be treated was performed in the reactor under the temperature stated in Table 2. The result is shown in Table 2.

### COMPARATIVE EXAMPLE 2

The processes and evaluations related to the frequency of occurrence of slip dislocation were carried out in the same way as in Comparative Example 1. However, in each process, in a step for transferring wafers so as to replace a treated wafer with a following wafer to be treated, the wafer loaded into the reactor was pre-heated to the temperatures shown in Table 2. The result is shown in Table 2.

TABLE 2

| | Wafer's loading and unloading temperature (Pre-heating temperature) | | | | | | |
|---|---|---|---|---|---|---|---|
| | 500° C. | 600° C. | 700° C. | 800° C. | 900° C. | 1000° C. | 1100° C. |
| Example | ◯ | ◯ | ◯ | ◯ | □ | □ | X |
| 2 | | | | | | | |
| Comp. | ◯ | □ | □ | X | — | — | — |
| Example | | | | | | | |
| 2 | | | | | | | |

Frequency of occurrence of slip dislocation
◯: smaller than 10%
□: equal to or larger than 10% □and smaller than 20%
X: equal to or larger than 20%
—: not evaluated

As shown in FIG. 2, if the wafer's loading and unloading temperature or pre-heating temperature was smaller than 500° C., in both methods; the wafer transfer method in accordance with the present invention and the conventional wafer transfer method accompanied with the pre-heating operation, the frequency of occurrence of slip dislocation of each wafer was smaller than 10%. That is to say, there is no striking difference between these methods.

However, if the wafer's loading and unloading temperature or pre-heating temperature was 600° C. to 800° C., the frequency of occurrence of slip dislocation was equal to or larger than 10% in the conventional method, on the other hand, it was smaller than 10% in the present method. That is to say, the yield of wafer products is improved in the present invention.

But even in the method in accordance with the present invention, if the wafer's loading and unloading temperature was equal to or higher than 900° C., the frequency of occurrence of slip of wafer was equal to or larger than 10%.

### EXAMPLE 3

With the single wafer processing vapor thin film growth system used in Example 1, by the wafer transfer method in accordance with the present invention, a silicon epitaxial film growth process for the silicon wafer was performed sequentially for 5 days. Then, the average number of treated wafers per day (productivity) was calculated. The result is shown in Table 3.

### COMPARATIVE EXAMPLE 3

With the single wafer processing vapor thin film growth system used in Comparative Example 1, by the same wafer transfer method of Comparative Example 1, a silicon epitaxial film growth process for the silicon wafer was performed sequentially for 5 days. Then, the average number of treated wafers per day (productivity) was calculated.

But in order to remove the impurities attached to the wafer support member, the film growth process with the vapor thin film growth system was shut down for about 64 minutes every 3 hours so that etching was performed with hydrogen chloride for the wafer support member in the vapor thin film growth system. The result is shown in Table 3.

TABLE 3

| | Productivity (sheets / day) |
|---|---|
| Example 3 | 206 |
| Comparative Example 3 | 152 |

As shown in Table 3, by the wafer transfer method in accordance with the present invention, the impurities attached to the wafer support member could be removed without the necessity of shut down of the epitaxial film growth process for the wafer. Accordingly, the productivity is further improved comparing with the conventional method.

In the single wafer processing vapor thin film growth process, the wafer transfer method in accordance with the present invention can relieve the heat shock applied to the wafer loaded into the reactor. Therefore, the occurrence of crystal defect such as slip dislocation is decreased.

Additionally, in this connection, the loading and unloading of wafer can be carried out under the high temperature. This enables quick heating and cooling.

Further, during heating and cooling, the temperature gap between several areas of the wafer (, particularly between the central area and peripheral area in the wafer,) can be decreased. Accordingly, the wafer can be cooled and heated uniformly throughout the global surface of the wafer.

Finally, the removing operation of the impurities attached to the wafer support member can be performed outside of the vapor thin film growth system without shutting down the vapor thin film growth process. Therefore, the productivity of the single wafer processing vapor thin film growth system can be improved.

What is claimed is:

1. A wafer transfer method performed with a single wafer processing vapor film growth system, which can continuously treat each wafer sheet by sheet and which heats the wafer from its back side surface, said system comprises at least a reactor, a heater for heating the wafer, a wafer support member for supporting the wafer and a support member which detachably holds said wafer support member, and said method comprises:
removing the wafer support member supporting a wafer, which has been subjected to a vapor film growth process, from the support member;
transferring the wafer support member supporting the wafer from the reactor having a temperature higher than a temperature of a room where said single wafer processing system is disposed;
transferring the wafer support member supporting another wafer, which is to be subjected to a vapor film growth process, into the reactor; and
holding the wafer support member by the support member.

2. A wafer transfer method according to claim 1, wherein said step for transferring wafers so as to replace them is carried out under the temperature of 500° C. to 1000° C.

3. A wafer transfer method according to claim 1, wherein said wafer support member is fabricated from the same material of said wafer.

4. A wafer transfer method according to claim 1, wherein said wafer support member has a recess for placing said wafer so that the depth of said recess has the substantially same dimension as the thickness of said wafer.

5. A wafer transfer method according to claim 1, wherein said wafer subjected to said film growth process is a silicon wafer.

6. A wafer support member used for a film growth system formed detachably attached to the support member of the single wafer processing vapor film growth system where said member is being fabricated from the same material of a wafer subjected to said film growth process and having a recess for placing said wafer so that the depth of said recess has the substantially same dimension as the thickness of said wafer.

7. A wafer transfer method according to claim 2, wherein said wafer support member is fabricated from the same material of said wafer.

8. A wafer transfer method according to claim 2, wherein said wafer support member has a recess for placing said wafer so that the depth of said recess has the substantially same dimension as the thickness of said wafer.

9. A wafer transfer method according to claim 2, wherein said wafer subjected to said film growth process is a silicon wafer.

10. A wafer support member according to claim 6, wherein said wafer support member is formed in ring shaped and supports only outer periphery member of the wafer.
